(19) United States
(12) Patent Application Publication
(10) Pub. No.: US 2014/0225335 A1
(43) Pub. Date: Aug. 14, 2014

(54) SUBSTRATE TREATMENT APPARATUS

(71) Applicant: KABUSHIKI KAISHA TOSHIBA, Minato-ku (JP)

(72) Inventor: Takehisa KURASHIMA, Mie-ken (JP)

(73) Assignee: KABUSHIKI KAISHA TOSHIBA, Minato-ku (JP)

(21) Appl. No.: 14/021,341

(22) Filed: Sep. 9, 2013

(30) Foreign Application Priority Data
Feb. 12, 2013 (JP) 2013-024831

(51) Int. Cl. H01L 21/683

(52) U.S. Cl. CPC H01L 21/6838; H01L 2221/683
USPC 279/3

(57) ABSTRACT

According to one embodiment, a substrate treatment apparatus includes a substrate holding unit including a holding unit configured to hold a target substrate, a base unit which has the holding unit on a peripheral portion thereof, and a hollow rotation shaft, which contains a gas supply channel, configured to rotate together with the holding unit and the base unit, the substrate holding unit configured to hold the target substrate by supplying to the target substrate gas supplied from the gas supply channel, a substrate rotating unit, which is connected to the rotation shaft through a belt, configured to rotate the substrate holding unit, and a first substrate holding detecting unit, which is connected to the substrate rotating unit, configured to detect whether or not the target substrate is held by the substrate holding unit, by measuring a rotational frequency or a roll acceleration of the rotating substrate holding unit.

### CROSS-REFERENCE TO RELATED APPLICATION

This application is based upon and claims the benefit of priority from Japanese Patent Application No. 2013-024831, filed Feb. 12, 2013, the entire contents of which are incorporated herein by reference.

### FIELD

Embodiments described herein relate generally to a substrate treatment apparatus.

### BACKGROUND

A substrate treatment apparatus with a wafer-by-wafer wafer system has been used in some cases when a substrate is processed with a treatment liquid supplied to the surface of a semiconductor wafer that is a substrate to be treated in a manufacturing process of a semiconductor device. Whether or not the target substrate put on the substrate treatment apparatus is normally held, is determined according to various methods.

In the substrate treatment apparatus, there may occur such an error that the target substrate is not properly held by the holding unit of the substrate holding unit but held in an inclined state, and that the substrate falls down on the bottom surface of the holding unit. This failure (error) in holding a substrate may be detected through measuring by an optical sensor whether or not a light illuminating the substrate holding unit in a substantially horizontal direction is transmitted without being disturbed by the target substrate.

In processing the back surface of the target substrate, in other words, a surface opposite to the surface (front surface) where a circuit is formed, using a treatment liquid, the front surface of the target substrate has to be held with no contact. As a non-contact substrate holding method, Bernoulli chuck of holding the target substrate by Bernoulli Effect may be used after injecting a gas toward the surface opposite to the surface to be processed of the target substrate. In a substrate processor of holding a substrate by Bernoulli chuck, for example, when a target substrate is carried from a carrying device to the substrate processor, even when the target substrate is not normally held because of the abnormal transfer operation, the conventional optical sensor cannot detect an error of holding the substrate because the target substrate is kept floating, namely, it does not incline nor fall down to the holding unit.

### DESCRIPTION OF THE DRAWINGS

FIG. 1 is a schematically cross-sectional view showing a substrate treatment apparatus according to an embodiment.

FIG. 2 is a cross-sectional view showing a substrate holding unit of the substrate treatment apparatus according to the embodiment.

### DETAILED DESCRIPTION

In general, according to one embodiment, there is provided a substrate treatment apparatus includes a substrate holding unit including a holding unit configured to hold a target substrate, a base unit which has the holding unit on a peripheral portion thereof, and a hollow rotation shaft, which contains a gas supply channel, configured to rotate together with the holding unit and the base unit, the substrate holding unit configured to hold the target substrate by supplying to the target substrate gas supplied from the gas supply channel, a substrate rotating unit, which is connected to the rotation shaft through a belt, configured to rotate the substrate holding unit, and a first substrate holding detecting unit, which is connected to the substrate rotating unit, configured to detect whether or not the target substrate is held by the substrate holding unit, by measuring a rotational frequency or a roll acceleration of the rotating substrate holding unit.

An embodiment will be described below in detail with reference to the attached drawings mentioned above.

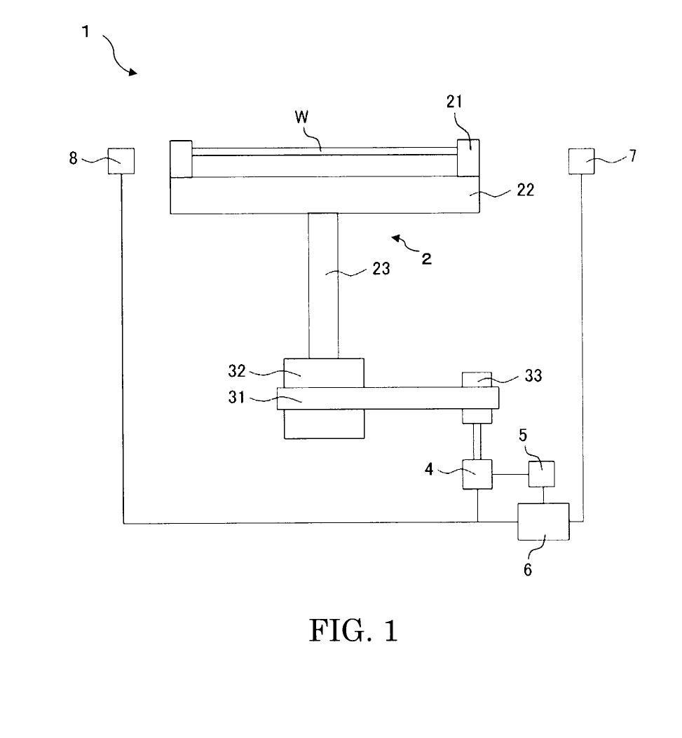

FIG. 1 is a schematically cross-sectional view showing a substrate treatment apparatus according to an embodiment.

A substrate treatment apparatus 1 is provided with a substrate holding unit 2 including a holding unit 21, a base unit 22, and a rotation shaft 23, a belt 31 which connects the rotation shaft 23 and a motor 4 (rotating unit), and a pulley 32 and a pulley 33 for connecting the belt 31. Further, the substrate treatment apparatus 1 is provided with a substrate holding detecting unit 5 which is adjacent to the motor 4 and a control unit 6 for controlling the substrate holding detecting unit 5.

The substrate holding unit 2 is provided with the holding unit 21 which guides and holds the target substrate W. Further, the substrate holding unit 2 is provided with the base unit 22 connected to the lower end of the holding unit 21. The holding unit 21 is provided on the peripheral portion of the base unit 22. The holding unit 21 and the base unit 22 do not have to be formed separately but may be formed integrally.

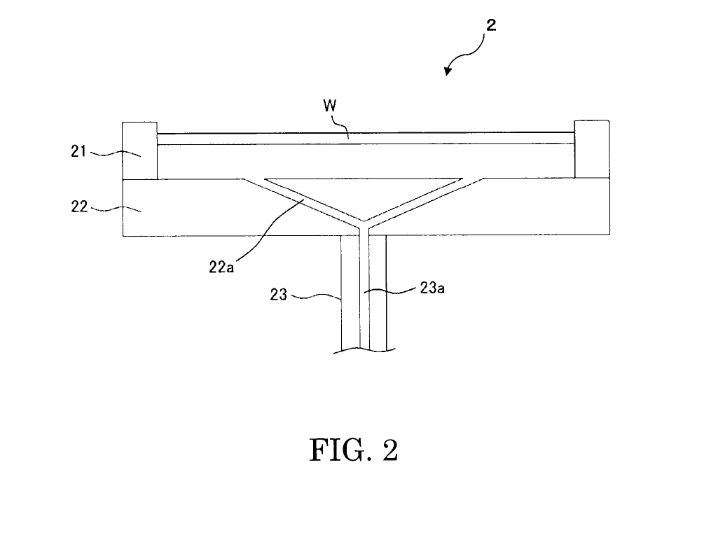

As described later, a gas supply channel 22a capable of supplying a gas flow is provided inside the base unit 22 so that the target substrate W can be held by the substrate holding unit 2 on a basis of to Bernoulli effect. As illustrated in FIG. 2, the gas supply channel 22a provided inside the base unit 22 is formed in that the gas supplied from the rotation shaft 23 branches, for example, in two directions and that the gas is supplied between the base unit 22 and the target substrate W. The gas supply channel 22a inside the base unit 22 preferably branches in order to supply the gas uniformly between the target substrate W and the base unit 22, alternatively, the gas supply channel does not have to branch. An inactive gas, for example, a nitrogen gas is used in the gas supply channel 22a.

The rotation shaft 23 is provided in the substrate holding unit 2 at the lower end of the base unit 22 in its substantial central portion. The rotation shaft 23 rotates due to the transmission of the power of the motor 4, hence to rotate the substrate holding unit 2 on the whole. Inside the rotation shaft 23, a gas supply channel 23a is provided in the extending direction of the rotation shaft 23, in order to supply gas to the gas supply channel 22a of the base unit 22.

The pulley 32 is provided on the lower end of the rotation shaft 23. The pulley 32 is connected to the pulley 33 connected to the motor 4, through the belt 31, to transmit the power caused by the rotation of the motor 4 to the rotation shaft 23. The belt 31 is provided to circle around the pulley 32 and the pulley 33.

Further, the substrate holding detecting unit 5 is provided to measure a rotational frequency or a roll acceleration of the motor 4. The substrate holding detecting unit 5 is, for example, an accelerometer which measures the acceleration of the motor 4, or a frequency sensor which measures the rotational frequency of the motor 4.

The substrate holding detecting unit 5 according to the embodiment is to detect a change of the value in the roll acceleration or the rotational frequency of the motor 4 varying according to whether or not the substrate holding unit 2 is holding the target substrate W. Concretely, the roll acceleration or the rotational frequency is previously measured in the case of holding the target substrate W by the substrate holding unit 2 and in the case of not holding the above, and the result is stored in a library (not shown). Then, the control unit 6 associates the value actually measured in the semiconductor manufacturing process with the value stored in the library, to determine whether or not the target substrate W is held by the substrate holding unit 2. The roll acceleration is measured, for example, by measuring a change in the speed for a predetermined time from starting the rotation of the motor 4. Concretely, when the rotational frequency or the roll acceleration measured by the substrate holding detecting unit 5 is larger than a predetermined value as compared with the value in a state of the target substrate W being held by the substrate holding unit 2, the control unit 6 stops the rotation of the motor 4.

Whether or not the target substrate W is held may be determined through the above measurement by providing the substrate holding detecting unit 5 on the rotation shaft 23. However, the roll acceleration or the rotational frequency of the rotation shaft 23 fluctuates larger caused by the weight of the base unit 22 and the target substrate W; therefore, it is difficult to determine a difference of fine value indicating whether or not the target substrate W is held by the substrate holding unit 2 by measuring the roll acceleration or the rotational frequency of the rotation shaft 23 by the substrate holding detecting unit 5.

According to the substrate treatment apparatus 1 of the embodiment, the substrate holding detecting unit 5 is connected to the motor 4 connected to the rotation shaft 23 through the belt 31, to measure the rotational frequency or the roll acceleration. Since the substrate holding unit 2 is connected to the motor 4 through the belt 31, the rotational frequency and the acceleration rarely fluctuate. Therefore, in a case that a substrate holding detecting unit 5 having a high resolution is used, the roll acceleration or the rotational frequency of the motor 4 is measured by the substrate holding detecting unit 5 connected to the motor 4, which can normally determine whether or not the target substrate W is held by the substrate holding unit 2.

Separately from the substrate holding detecting unit 5 connected to the motor 4, an optical sensor 7 may be provided in the substrate treatment apparatus 1. Holding of a substrate is detected by the optical sensor 7; whether or not a light illuminating the substrate holding unit 2 from a light illuminating unit 8 in a substantially horizontal direction is transmitted without being disturbed by the target substrate W is measured by the optical sensor 7. In such a manner, a more accurate substrate holding detection is enabled in combination with the above substrate holding detecting unit 5.

After determining that the target substrate W is held by the substrate holding unit 2, according to the above mentioned substrate treatment apparatus 1, a treatment liquid is supplied to the target substrate W from a treatment liquid supply nozzle (not illustrated), thereby processing the target substrate W.

As mentioned above, according to the substrate treatment apparatus of the embodiment, the substrate holding detecting unit is provided adjacent to the motor connected to the rotation shaft through the belt. In such a manner, since the substrate holding unit is connected to the motor through the belt, the rotational frequency and the acceleration hardly fluctuate, so that whether or not the target substrate W is held by the substrate holding unit can be normally determined.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A substrate treatment apparatus, comprising:
a substrate holding unit including a holding unit configured to hold a target substrate, a base unit which has the holding unit on a peripheral portion thereof, and a hollow rotation shaft, which contains a gas supply channel, configured to rotate together with the holding unit and the base unit, the substrate holding unit configured to hold the target substrate by supplying to the target substrate gas supplied from the gas supply channel;
a substrate rotating unit, which is connected to the rotation shaft through a belt, configured to rotate the substrate holding unit; and
a first substrate holding detecting unit, which is connected to the substrate rotating unit, configured to detect whether or not the target substrate is held by the substrate holding unit, by measuring a rotational frequency or a roll acceleration of the rotating substrate holding unit.

2. The apparatus according to claim 1, further comprising:
a control unit configured to stop a rotation of the rotating unit when a measurement value of the rotational frequency or the roll acceleration measured by the first substrate holding detecting unit is larger than a predetermined value as compared with the rotational frequency or the roll acceleration in a state of the target substrate being held by the substrate holding unit.

3. The apparatus according to claim 2, wherein
the control unit includes a library and stores measured results of the roll acceleration or the rotational frequency in the library, where the measured results are previously measured in cases of holding the target substrate by the substrate holding unit and not holding the target substrate by the substrate holding unit.

4. The apparatus according to claim 3, wherein
the control unit associates the measurement value with the measured results stored in the library to determine whether or not the target substrate

5. The apparatus according to claim 4, wherein
the control unit stops the rotation of the substrate rotating unit when the measurement value of the roll acceleration or the rotational frequency is larger than the measured result of the roll acceleration or the rotational frequency.

6. The apparatus according to claim 1, wherein
the substrate rotating unit includes a motor and the rotation shaft rotates due to the transmission of the power of the motor.

7. The apparatus according to claim 3, wherein
the roll acceleration or the rotational frequency of the substrate rotation unit is obtained by measuring a roll acceleration or a rotational frequency of the motor.

8. The apparatus according to claim 1, wherein
the substrate rotation unit includes a rotation sensor which measures the rotational frequency.

9. The apparatus according to claim 1, wherein
the substrate rotation unit includes an acceleration sensor which measures the roll acceleration.

10. The apparatus according to claim 1, wherein
the gas supply channel supplies the gas between the target wafer and the base via the base.

11. The apparatus according to claim 10, wherein
the gas supply channel in the base includes a plurality of channels.

12. The apparatus according to claim 1, further comprising:
a second substrate holding detecting unit configured to measure a light illuminated between the target substrate and the base unit in the substrate holding unit in order to detect whether or not the target substrate is held by the substrate holding unit.

13. The apparatus according to claim 12, further comprising:
a light illuminating unit illuminating the light between the target wafer and the base unit.

14. The apparatus according to claim 13, wherein
holding of the substrate is detected by measuring using the optical sensor whether or not the light illuminating the substrate holding unit from the light illuminating unit in a substantially horizontal direction is transmitted without being disturbed by the target substrate.

15. The apparatus according to claim 1, wherein
the belt is arranged to circle around a first pulley provided on a lower end of the rotating unit and a second pulley provided to be connected to the rotating unit.

16. The apparatus according to claim 1, wherein
the target substrate is held on a basis of Bernoulli effect by the substrate holding unit.

17. The apparatus according to claim 1, further comprising:
a treatment liquid supply nozzle,
wherein a treatment liquid is supplied to the target substrate from the treatment liquid supply nozzle to process the target substrate.
